(19) United States
(12) Patent Application Publication
(10) Pub. No.: US 2026/0180690 A1
(43) Pub. Date: Jun. 25, 2026

(54) DUAL CONTRA-FOCAL HOMOGENIZER

(71) Applicant: LASERMOTIVE, INC., Kent, WA (US)

(72) Inventors: Thomas J. NUGENT, JR., Bellevue, WA (US); Sergiy DETS, Calgary, CA (US)

(21) Appl. No.: 18/711,587

(22) PCT Filed: Nov. 18, 2022
(86) PCT No.: PCT/US2022/080173

§ 371 Date: May 18, 2024

Related U.S. Application Data
(60) Provisional application No. 63/281,618, filed on Nov. 19, 2021.

(51) Int. Cl. G02B 27/09; G02B 5/02; G02B 27/30; H01S 3/00

(52) U.S. Cl. CPC G02B 27/0927; G02B 5/0278; G02B 27/0977; G02B 27/30; H01S 3/005

(57) ABSTRACT

A power receiver includes a beam homogenizer that takes portions of a power beam and spreads them to each cover a substantial fraction (or all) of a power converter surface. The beam homogenizer may lack reflective side walls, and may have an aspect ratio as low as 2-5. The normalized deviation of beam irradiance at the surface may be reduced by a factor of 2-5 or more.

### BACKGROUND

Power beaming is an emerging method of transmitting power to places where it is difficult or inconvenient to access using wires, by transmitting a beam of electromagnetic energy to a specially designed receiver which converts it to electricity. Power beaming systems may be free-space (where a beam is sent through atmosphere, vacuum, liquid, or other non-optically-designed media), or power-over-fiber (“PoF”), where the power is transmitted through an optical fiber. The latter may share certain disadvantages with wires in some circumstances, but may also offer increased transmission efficiency, electrical isolation, and/or safety. Free-space power beaming may be more flexible, but it may also offer more challenges for accurate targeting of receivers and avoiding hazards such as reflections and objects intruding on the power beam.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventors' approach to the particular problem, which in and of itself may also be inventive.

### SUMMARY

In one aspect, a beam homogenizer includes a compound lens configured to reshape an incident power beam. The compound lens includes a first optical surface configured to focus the incident power beam at a focal distance, and a second optical surface including a plurality of optical elements. Each optical element of the plurality is configured to expand a respective portion of the focused power beam toward a light-gathering area, and the directed portions of the focused power beam each overlap with one another at the light-gathering area to form a homogenized power beam. In a related aspect, a power receiver includes the beam homogenizer described above and a power converter positioned to receive the homogenized power beam.

In another aspect, a method of homogenizing a power beam includes receiving an incident power beam, splitting the received beam into a plurality of beam portions, and directing each beam portion toward a beam target area. Directing each beam portion includes changing the size of the beam portion at the target area to a selected size. The plurality of beam portions overlap with one another at the target area.

### BRIEF DESCRIPTION OF FIGURES

The drawing figures depicts one or more implementations in according with the present teachings, by way of example only, not by way of limitation. In the figures, like reference numerals refer to the same or similar elements. Furthermore, it should be understood that the drawings are not necessarily to scale.

FIG. 1 is a schematic diagram of a power beaming transmitter and receiver.

FIG. 2 is a functional diagram of the power beaming transmitter of FIG. 1, showing interrelationships between components of the transmitter.

FIG. 3 is a functional diagram of the power receiver of FIG. 1, showing interrelationships between components of the receiver.

FIG. 4 is a schematic diagram showing principles of operation of a homogenization lens.

FIG. 5 is a first-stage hybrid homogenization lens.

FIG. 6 is schematic diagram including a homogenization lens, which differs from the lens of FIG. 4 by using convex (converging) lenslets instead of concave (diverging) lenslets.

FIG. 7 shows the response of the lens of FIG. 6 when light enters off-axis.

FIG. 8 shows a module including a homogenization lens and concentrators.

FIG. 9 is a secondary polygonal concentrator that matches a PV cell in size and relies on a single reflection at a grazing incident angle to minimize losses.

FIG. 10(a) shows an incoming collimated beam with a Gaussian profile. FIG. 10(b) shows the beam just before it enters the concentrators, and FIG. 10(c) shows the beam just before it enters the PV cells. These three figures may be referred to collectively herein as FIG. 10.

FIG. 11(a) shows an incoming collimated beam with a Gaussian profile, which is significantly shifted with respect to optical axis of before it enters the module shown in FIG. 8. FIG. 11(b) shows the beam just before it enters the concentrators, and FIG. 11(c) shows the beam just before it enters the PV cells. These three figures may be referred to collectively herein as FIG. 11.

FIG. 12(a) shows an incoming collimated beam with a Gaussian profile entering a 3×3 catadioptric array of the modules shown in FIG. 8. FIG. 12(b) shows the beam just before it enters the concentrators, and FIG. 12(c) shows the beam just before it enters the PV cells. These three figures may be referred to collectively herein as FIG. 12.

FIG. 13(a) shows an incoming collimated beam with a Gaussian profile entering a 3×3 catadioptric array of the modules shown in FIG. 8, which differs from the beam shown in FIG. 12(a) only in that it is offset from the center of the array. FIG. 13(b) shows the beam just before it enters the concentrators, and FIG. 13(c) shows the beam just before it enters the PV cells. These three figures may be referred to collectively herein as FIG. 13.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high level, without detail, in order to avoid unnecessarily obscuring aspects of the present teachings. Those of ordinary skill in the art will nevertheless understand the features of these methods, procedures, components, and/or circuitry and how they may be used in the descriptions below. Other relevant material may be found in other patents and applications as follows:

| | | |
|---|---|---|
| U.S. Pat. No. 9,800,091 | Issued Oct. 24, 2017 | Aerial Platform Powered Via an |
| | | Optical Transmission Element |
| U.S. Pat. No. 10,825,944 | Issued Nov. 3, 2020 | Device for Converting Electromagnetic |
| | | Radiation into Electricity, and Related |
| | | Systems and Methods |
| U.S. Pat. No. 10,634,813 | Issued Apr. 28, 2020 | Multi-Layered Safety System |
| U.S. Pat. No. 10,816,694 | Issued Oct. 27, 2020 | Light Curtain Safety System |
| U.S. Pat. No. 11,105,954 | Issued Aug. 31, 2021 | Diffusion Safety System |
| International Application | Filed May 18, 2016 | Power Beaming VCSEL Arrangement |
| No. PCT/US16/33117 | | |
| U.S. Pat. No. 10,488,549 | Issued Nov. 26, 2019 | Locating Power Receivers |
| U.S. Pat. No. 10,459,114 | Issued Oct. 29, 2019 | Wireless Power Transmitter and |
| | | Receiver |
| U.S. Pat. No. 10,374,466 | Issued Aug. 6, 2019 | Energy Efficient Vehicle with |
| | | Integrated Power Beaming |
| U.S. Pat. No. 11,368,054 | Issued Jun. 21, 2022 | Remote Power Safety System |
| U.S. Pat. No. 10,673,375 | Issued Jun. 2, 2020 | Power-Over-Fiber Receiver |
| U.S. Pat. No. 10,580,921 | Issued Mar. 3, 2020 | Power-Over-Fiber Safety System |
| U.S. application Ser. No. | Filed Nov. 19, 2021 | Remote Power Beam-Splitting |
| 17/613,015 | | |
| U.S. application Ser. No. | Filed Nov. 19, 2021 | Safe Power Beam Startup |
| 17/613,021 | | |
| U.S. application Ser. No. | Filed Nov. 19, 2021 | Beam Profile Monitor |
| 17/613,028 | | |
| U.S. application Ser. No. | Filed Mar. 15, 2022 | Optical Power for Electronic Switches |
| 17/760,731 | | |
| U.S. application Ser. No. | Filed Nov. 2, 2020 | Dual-Use Power Beaming System |
| 17/087,198 | | |
| International Application | Filed Jan. 24, 2022 | Power Receiver Electronics |
| No. PCT/US22/13570 | | |
| U.S. application Ser. No. | Filed Jan. 21, 2022 | Light Curtain System with Enhanced |
| 17/581,667 | | Geometric Configurations |
| U.S. application Ser. No. | Filed Nov. 14, 2021 | Beam Homogenization at Receiver |
| 18/054,867 | | |
| U.S. Provisional Application | Filed Apr. 19, 2022 | Power Receivers and High Power Over |
| No. 63/332,663 | | Fiber |
| U.S. Provisional Application | Filed Jul. 22, 2022 | Power Receiver Electronics |
| No. 63/369,146 | | |

Each of these related applications and patents is incorporated by reference herein to the extent not inconsistent herewith.

As discussed above, power beaming is becoming a viable method of powering objects in situations where it is inconvenient or difficult to run wires. For example, free-space power beaming may be used to deliver electric power via a ground-based power transmitter to power a remote sensor, to recharge a battery, or to power an unmanned aerial vehicle (UAV) such as a drone copter, allowing the latter to stay in flight for extended periods of time. Power over fiber (PoF) systems usually require optical fiber (or an equivalent) to be run from a power source to a receiver, but may nevertheless provide electrical isolation and/or other advantages over traditional copper wires which carry electricity instead of light.

It will be understood that the term “light source” is intended to encompass all forms of electromagnetic radiation that may be used to transmit energy, and not only visible light. For example, a light source (e.g., a diode laser, fiber laser, light-emitting diode, magnetron, or klystron) may emit ultraviolet, visible, infrared, millimeter wave, microwave, radio waves, and/or other electromagnetic waves, any of which may be referred to herein generally as “light.” The term “power beam” is used herein interchangeably with “light beam” to mean a high-irradiance transmission, generally directional in nature, which may be coherent or incoherent, of a single wavelength or multiple wavelengths, and pulsed or continuous. A power beam may be free-space, PoF, or may include components of each. For example, a transmitter may transmit a free-space power beam to a receiver surface, which may conduct it as light over an optical fiber to a photovoltaic (PV) cell which converts it to electricity. For the sake of readability, the description may use the term “laser” to describe a light source; nevertheless, other sources such as (but not limited to) light-emitting diodes, magnetrons, or klystrons may also be contemplated unless context dictates otherwise.

For many applications, a power receiver is arranged to receive the free-space or PoF power beam and convert it to electricity, for example using PV cells or other components for converting light to electricity (e.g., a rectenna for converting microwave power or a heat engine for converting heat generated by the light beam to electricity). For the sake of readability, this application may refer to “PV cells” with the understanding that other components having a similar function (such as but not limited to those listed above) may be substituted without departing from the scope of the application.

### Power Beaming Systems

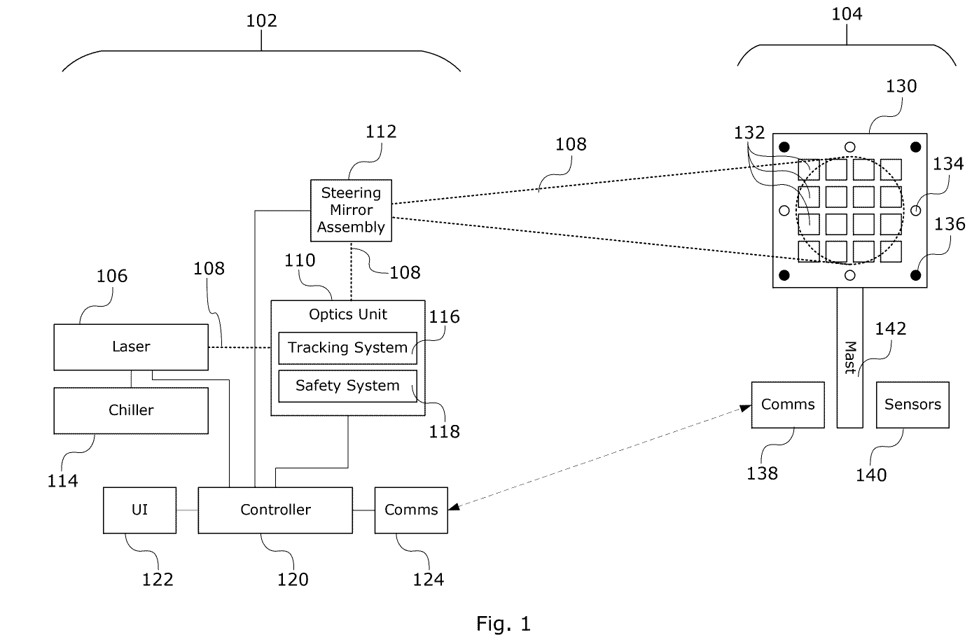

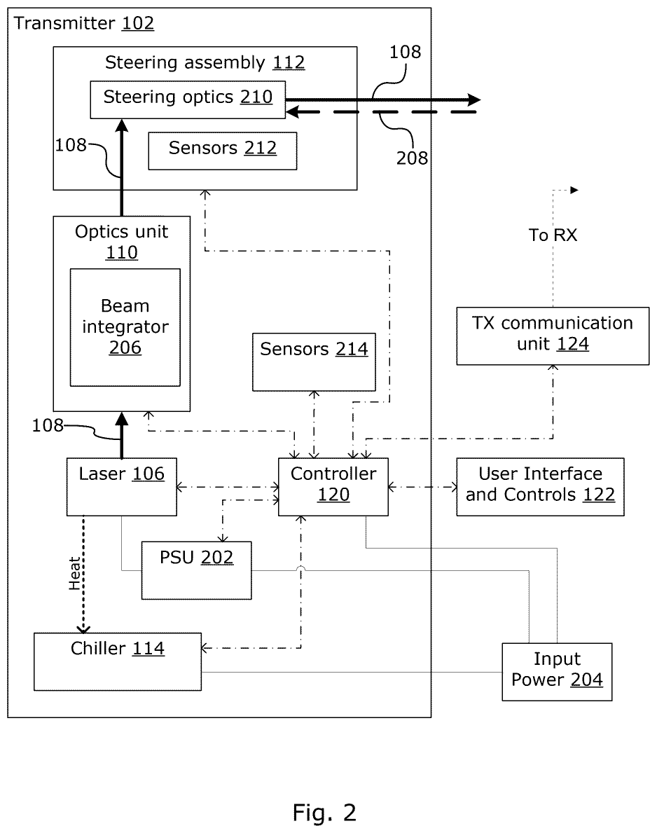

FIG. 1 is a schematic diagram of a power beam transmitter 102 and receiver 104. Laser 106 directs a power beam 108 (shown throughout the diagram as a dotted line) toward optics unit 110, which directs the beam to a beam steering assembly, such as mirror assembly 112. Optics unit 110 may include various lenses, mirrors, and other optical elements, as further discussed below. Steering mirror assembly 112 directs power beam 108 to power receiver 104. Optional chiller 114 is shown as connected to laser 106, but other components of transmitter 102 may also have independent or connected thermal management systems as required. Also shown in FIG. 1 as part of transmitter 102 are tracking system 116 and safety system 118. These systems are shown as being internal to optics unit 110 in the figure, but those of ordinary skill in the art will recognize that in some implementations, they may be external to optics unit 110, part of steering mirror assembly 112, or elsewhere in the transmitter system. Also shown are TX controller 120, user interface 122 and TX communication unit 124, all of which are further discussed below in connection with FIG. 2. It will be understood that transmitter 102 may include other elements, such as beam shapers, guard beams, or other appropriate accessory elements, that have been omitted from FIG. 1 for the sake of simplicity of the illustration. Some of these elements are shown schematically below in FIG. 2, but those of ordinary skill in the art will understand how to combine optical and control elements in a power transmitter.

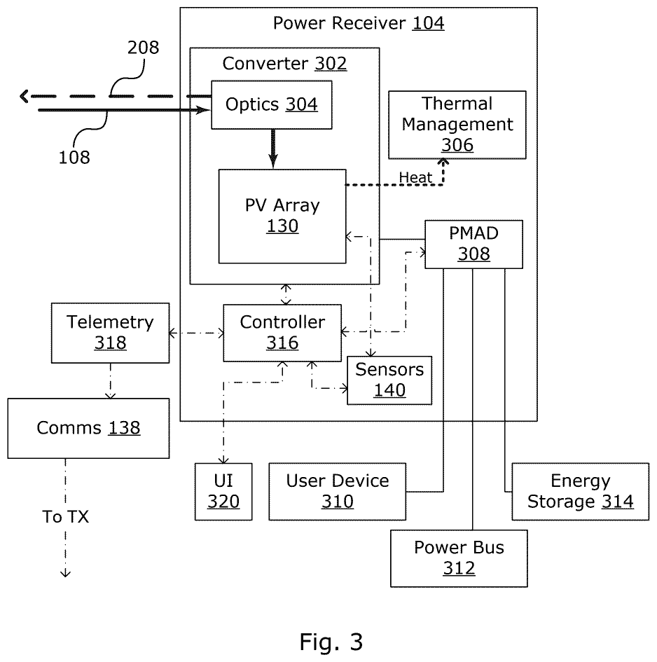

Receiver 104 includes a PV array 130, which includes a plurality of individual PV cells 132 (not all PV cells are labeled in order to avoid unnecessarily cluttering the figure). PV cells 132 convert incoming power beam 108 into electricity as further described below. Receiver 104 also shows tracking emitters 134, which in some implementations may be used by the tracking system 116 to monitor the position of PV array 130 for beam tracking or for other purposes. Receiver 104 also shows safety emitters 136, which in some implementations may be used by safety system 118 to monitor power beam 108 for potential intrusions, reflections, or other safety hazards. RX communication unit 138 is in communication with TX communication unit 124 (as indicated by the dashed line), and may be used for safety, tracking, telemetry, feedback control, or any other purpose for which it may be desirable for transmitter 102 and receiver 104 to communicate. While the illustrated embodiment provides communication across a separate channel such as a radio link between transmitter 102 and receiver 104, it is also contemplated that communication may be accomplished via modulation of power beam 108, tracking emitters 134, safety emitters 136, or other existing components of the power beaming system. Receiver 104 may also include optional RX sensors 140, further described below in connection with FIG. 3. As shown in FIG. 1, PV array 130 is mounted on optional mast 142, which may elevate receiver 104 to allow power beam 108 to avoid humans or other obstacles.

FIG. 2 is an abstracted diagram showing functional relationships between components of the transmitter. Transmitter 102 includes a laser 106, but it will be understood that other light-generating components, such as an LED or a magnetron, may be substituted for laser 106 in some implementations. Laser 106 is connected to controller 120, power supply unit (PSU) 202 (which is in turn connected to input power 204), and a thermal management system (chiller) 114. Throughout FIG. 2 and FIG. 3, heat flow is denoted by heavy dotted lines, while power beam 108 is denoted by a heavy solid line, sensor signals are denoted by heavy dashed lines, data and/or control signals are denoted by dot-dashed lines, and electrical power is indicated by a thin solid line. For the sake of clarity, not all internal electrical connections are shown.

Controller 120 controls operation of laser 106 and may be manual (for example using a user interface 122), partially automated, or fully automated, depending on design constraints of the system. In particular, controller 120 may receive input from a safety system, for example as described in commonly owned U.S. Pat. Nos. 10,634,813 and 10,816,694, U.S. patent application Ser. Nos. 15/574,659 and 16/079,073, International Patent Application No. PCT/US20/34104, and U.S. Provisional Application No. 63/140,236. The safety system may be designed to turn down or to turn off the beam, for example when an uninterrupted optical path from transmitter 102 to receiver 104 cannot be assured or when other hazardous conditions may be associated with continuing to beam power. Controller 120 may receive input (data) from other components, for example to monitor the health or temperature of the laser. PSU 202 draws power from input power 204, which may be, for example, a power grid, a generator, or a battery, and supplies it to laser 106. In the figure, controller 120 and chiller 114 are directly connected to input power 204, but in other embodiments, these or other components may receive power from power supply unit 202. Chiller 114 monitors the temperature of laser 106 (and/or other components of the transmitter as necessary) and makes sure it does not exceed safe values.

As shown in FIG. 2, power beam 108 emerges from light source 106 and enters optics unit 110. It will be understood that while light 108 maintains the same reference numeral throughout FIG. 2, the characteristics of light 108 may change in various ways (e.g., polarization, convergence/divergence angle, beam profile, or intensity) as it passes through different optics and other components. Optics unit 110 may include beam integrator 206 and other optics such as lenses, mirrors, phased arrays, or any other appropriate component for managing direction, divergence, and beam irradiance profile of the light, or for merging different optical power beams and/or signals. Beam integrator 206 will generally be chosen to match the wavelength domain of light source 106, and can be used to change the size, shape, or intensity distribution of the power beam. For example, when beaming power to a receiver, it may be desirable in some implementations to match the beam width to the size of the receiver, and possibly to “flatten” the beam irradiance profile to be relatively uniform across a surface of the receiver, for example converting a substantially Gaussian beam profile to a “top hat” or super-Gaussian profile. Beam direction and beam profile shaping is discussed in more detail in co-pending and commonly owned International Patent Application No. PCT/US20/34095. In particular, the mechanisms described therein for monitoring the placement of a power beam on a receiver and using the monitored data to feed back to controller 120 and/or to steering assembly 112 may be incorporated into the present system.

Steering assembly 112 may include steering optics 210 and/or sensors 212, which may be used in some implementations to provide feedback information for tracking the receiver and pointing the beam at it, to measure the beam characteristics such as direction or irradiance profile, or to monitor for potential intrusions into the light path. Steering assembly 112 may also include merging optics. Merging optics are generally used for combining multiple optical paths, or possibly for separating them when optical flow is in the opposite direction. For example, an outgoing power beam 108 for transmitting power may be combined with an incoming optical beacon 208 used for tracking a receiver, as shown in the figure. As illustrated, the beacon is used at steering assembly 112 for tracking, but in other implementations, signal 208 may propagate to optics unit 110 or beyond.

Transmitter 102 may also be provided with sensors 214, which may be used to monitor ambient conditions. Sensors 212, 214 may be used to adjust beam integrator 206 and/or steering optics 210. For example, sensors 212 might monitor position of a focusing lens or other optical component in steering assembly 112, while sensors 214 might be used to monitor ambient and/or other component temperatures. Data from sensors 212, 214 may be fed back into controller 120 to adjust laser 106, for example for safety considerations, or to control steering optics 210 and/or steering assembly 112 to direct beam 108 onto the receiver. Control and data signals may pass between controller 120 and other components, as shown by dot-dashed lines in FIG. 2, and controller 120 may control communication with the receiver, for example using transmitter communication unit 124.

After passing through optics unit 110, power beam 108 is directed by steering assembly 112 in a desired direction away from transmitter 102. In some implementations, steering assembly 112 may include steering optics 210, motors for adjusting mirrors or other components (not shown), and/or more shaping optics (not shown). Those of ordinary skill in the art will understand that different implementations may require different arrangements of optical elements (such as the order of components that the light passes through) without changing the fundamental nature of the transmitter system.

FIG. 3 shows functional relationships between components of a power receiver 104, such as the receiver shown in FIG. 1. Illustrated receiver 104 includes power converter 302, which includes PV array 130 of PV cells 132. Power converter 302 is configured to convert power beam 108 from laser 106 into electricity (or, in some implementations, into another useful form of energy). Receiver 104 may also include optics 304, which may shape or modify the received beam before it reaches PV array 130, for example as described in International Application No. PCT/US20/34093. In many implementations, PV array 130 includes a thermal management system 306. This system may include passive or active cooling, and it may be configured to send a signal back to transmitter 102 if any part of PV array 130 exceeds safe temperature limits (for example, via RX communication unit 138).

Power converter 302 may further be connected to power management and distribution (PMAD) system 308. PMAD system 308 may power user devices 310, a power bus 312, and/or energy storage devices 314. PMAD system 308 may be connected to controller 316, which may monitor PV array 130 via sensors 140, for example monitoring voltage, current, and/or temperature of individual photovoltaic cells, groups of cells, or of the whole array, voltage and/or current of the PMAD or of individual loads. Controller 316 may also include Maximum Power Point Tracking (MPPT) for PV array 130, or MPPT may be handled by PMAD system 308. PMAD system 308 may also include DC/DC converters, for example to provide power to devices 310, 312, 314 with preferred voltage and current characteristics. Telemetry unit 318 may send any or all of the above data back to the transmitter for use in controlling light beam 108, for example through RX communications unit 138. In some implementations, controller 316 may communicate with a receiver user interface 320, which may allow local viewing and/or control of receiver operations by a user of the power receiver.

Also visible in FIG. 3 is a signal 208 (e.g., an optical signal) being sent back to transmitter 102 by receiver 104, which may be sent along the same path as power beam 108 as shown. In some implementations, for example, signal 208 may include a safety signal that is used to assure an uninterrupted path from transmitter 102 to receiver 104. In some implementations, this signal may be sent from safety emitters 136. More details on safety systems may be found, for example, in commonly owned U.S. Pat. Nos. 10,580,921, 10,634,813, 10,816,694, and 11,105,954, U.S. patent application Ser. No. 16/079,073, and International Patent Application No. PCT/US20/34104. In some implementations, signal 208 may include a tracking signal that is used to position power beam 108 on power converter 302, such as a signal sent from tracking emitters 134. While signal 208 as shown in the figure is an “active” signal, in other implementations, emitters 134, 136 may be replaced by fiducial marks (not shown) that are identified by transmitter 102 or by other appropriate components in the power transmission system.

Any receiver components that require power, for example but not limited to thermal management system 306, RX communication unit 138, PMAD system 308, controller 316, telemetry unit 318, and/or user interface 320, may be powered by power converter 302 (directly or via PMAD 308) if desired. If components are powered by converter 302, the system might include a battery (either as part of energy storage 314 or as a separate component) to power these components during start-up or at other times when converter 302 is not supplying power.

### Beam Reshaping

While it is preferred to deliver a beam with a super-Gaussian or nearly “flat top” intensity profile at the receiver, in some cases a “plain” Gaussian beam may be delivered instead, for example because of distance to the receiver. Even super-Gaussian beams have “tails” in their intensity profiles, which can limit array performance because the PV cells near the perimeter of the PV array may receive little or no light. Overfilling the array to put light on all of them reduces efficiency due to wasted light, and potentially causes a safety hazard from light spilling past the receiver. The cells have an input power level per cell above which they lose efficiency and may eventually overheat, and so the peak power intensity of the beam (usually near the center of the beam) may drive the overall number of cells required for a given power output. Furthermore, scintillation can cause individual PV cells to register a quickly and widely varying intensity, both above and below the nominal intensity, which can degrade efficiency for a variety of reasons. The present design homogenizes the beam, at least partially, so that the range of intensities on individual cells in an array is effectively reduced by shifting some light to the outermost cells, which enables higher array power output for a given number of cells.

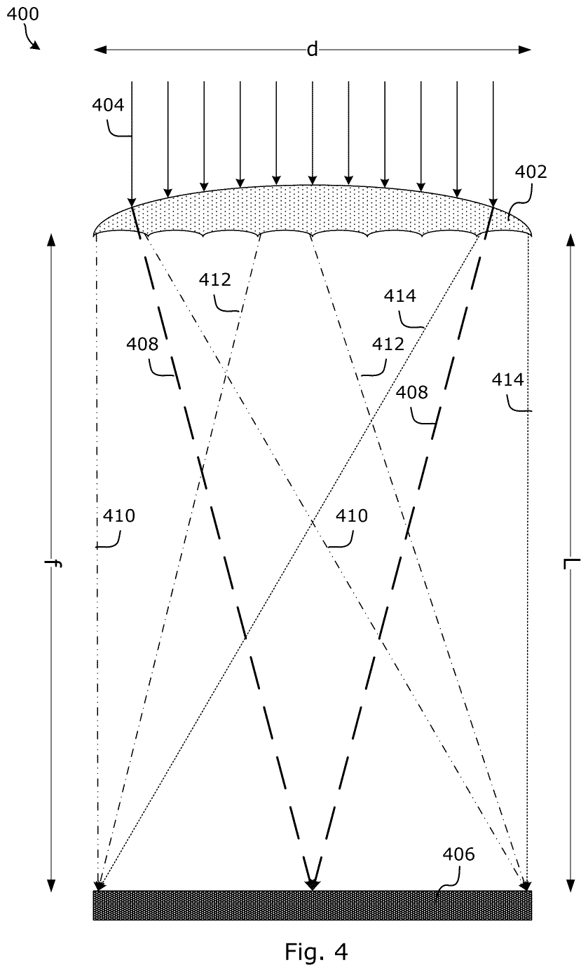

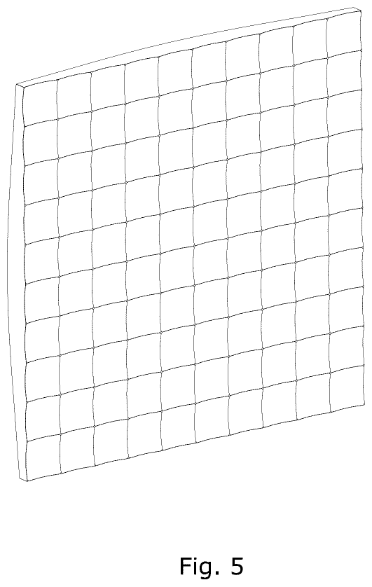

FIG. 4 is a schematic diagram for purposes of understanding the invention. Angles and distances are not necessarily to scale. As shown, assembly 400 includes a square compound refractive lens 402 (shown in cross-section in FIG. 4 and in perspective in FIG. 5) that receives incoming collimated light 404 (e.g., from a laser power beam). Lens 402 has a width of d and its upper surface has a convex shape having a focal length of f (and thus an f-number of f/d). Thus, without considering the effect of the bottom surface, it would focus light 404 onto a surface 406 at distance f away from the lens, as shown by heavy dashed lines 408. In the example shown in FIG. 4, the focal length f and working distance L are equal, but as will be discussed below, this is not a requirement. The working distance L may differ from the focal length in other implementations, and the top shape may be any suitable shape (e.g., spherical, aspherical, or freeform). In the implementation shown in FIG. 4, the lower surface of lens 402 is tiled with an arrangement of square concave lenslets having a negative f-number of about the same magnitude as that of the top surface. These lenses each thus spread light back out to approximately the width of the original beam at a plane of distance L away from the lens, as shown by pairs of dotted and dot-dashed lines 410, 412, 414. The combination effectively homogenizes the beam, since each of the lenslets of the bottom surface spreads a portion of the incoming beam across the whole (or nearly the whole) target plane, since the beam portion from each individual lenslet is angled towards the center of target surface 406 due to its refraction from the first surface. Thus, the effect of the entire lenslet array is to flatten the beam profile and to mitigate the effects of scintillation or other beam inhomogeneity. Notably, very little light escapes the width of a right cylinder projected down from the cross-section of the lens 402, even though no side reflectors are provided, and light arriving at the target plane is closer to normal to the plane than it would be with standard diffuser systems, which tend to spread the beam. This is important because PV cells may have a limited acceptance angle for light, or at least may have improved efficiency when light is as close to normal to their surface as possible. In some implementations, the f-number of the concave lenslets may be slightly greater, so that the light diverges more slowly but still arrives at an overlapping area at working distance L. As illustrated, target surface 406 has the about the same width as lens 402, but of course in some implementations it might be narrower, as long as it is at least wide enough to capture most or all of the incoming beam.

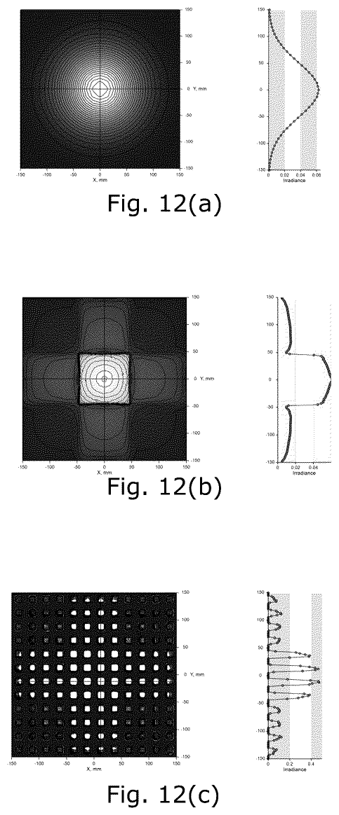

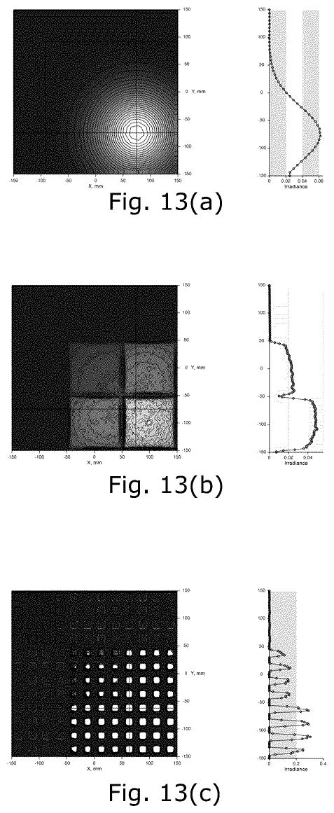

In some implementations, the target surface 406 may be somewhat larger or smaller than lens 402, but is still shaped according to the same principle that each lenslet spreads its own section of the incoming light 404 across an overlapping target area, which as illustrated in FIG. 4 is almost as large as lens 402. In some implementations, the target area is at least 25%, at least 50%, at least 75%, at least 90%, or at least 95% of the width of target surface 406. The target area 406 may also be wider (for example, 110% or 125%) than the lens 402, but in these cases the degree of homogenization will be somewhat reduced at the periphery of target surface 406, and it may be more difficult to assemble multiple modules as discussed below in connection with FIG. 12 and FIG. 13.

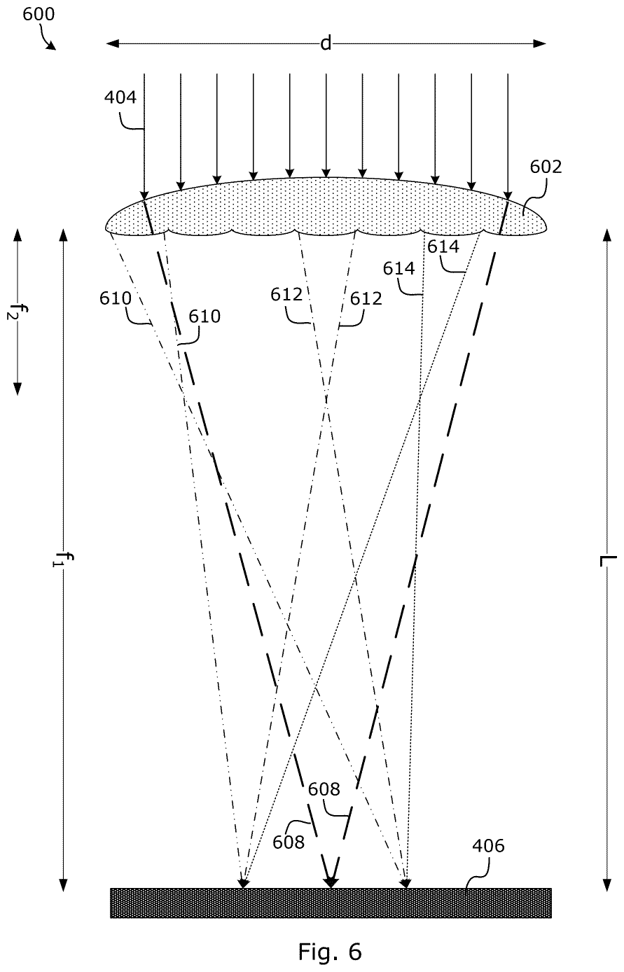

FIG. 6 shows an assembly 600 including alternate refractive lens 602 that uses convex lenslets on its bottom surface. The upper surface still has the same focal length (now marked as f₁), but the lenslets have a smaller, positive focal length f₂, selected so that light coming from each lenslet (610, 612, 614) converges to a point well before reaching target surface 406, then diverges to spread across the same target area of the surface. In this illustration, f₂ is chosen to reach a smaller overlapping area than shown in FIG. 4, about 35% of the width (so about 12% of the area) of target surface 406. It will be apparent to those of ordinary skill in the art that different implementations may include concentrating (as illustrated) or spreading out incoming light to different degrees, without changing the principles of the invention.

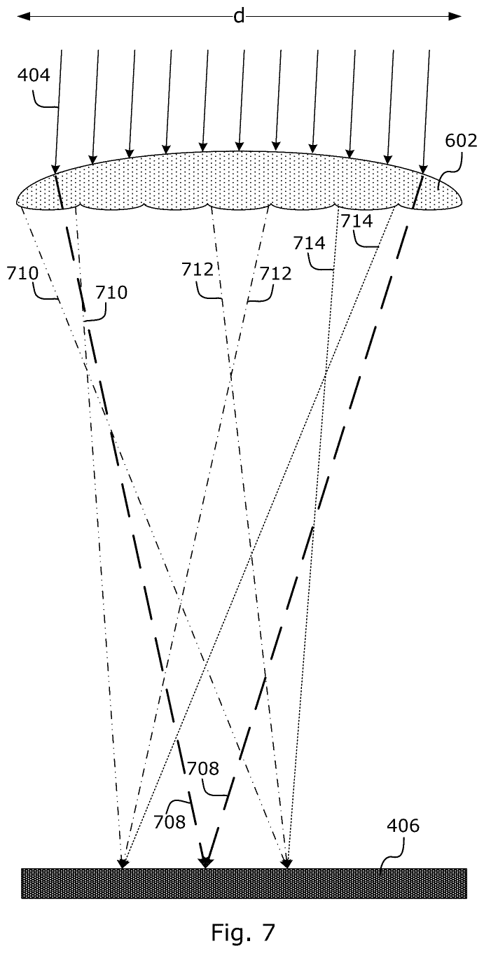

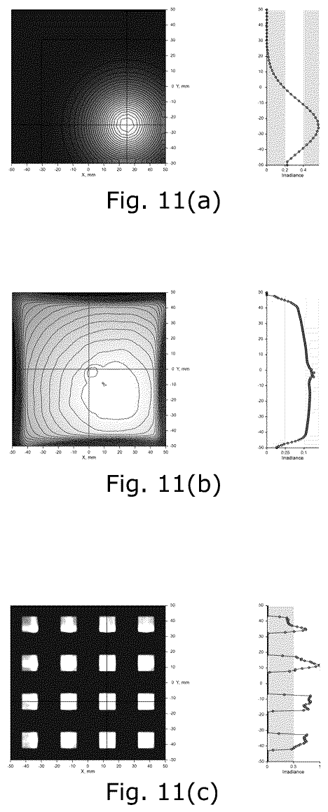

Those of ordinary skill in the art will further understand how to select the f-numbers of lenses 402, 602 to contain light on target surface 406, spreading it evenly across the target plane while not losing light off the edges. Although this is most easily illustrated and understood in the context of a lens as shown in FIG. 4-FIG. 6, those of ordinary skill in the art will also appreciate that the same principles can apply to reflective optics or to diffractive optical elements (DOEs), which may provide a lighter and/or more compact system, and may also improve a light-induced damage threshold for the system. Lenslets may be somewhat larger than typical microlenses, for example about 0.1-3 cm across. An advantage of the system is that a modest change in the angle of collimated light 404 entering the system shifts the location of projected light on target surface 406, but maintains the overlapping areas, as can be seen more clearly in FIG. 7. Lens 602 has the same shape as in FIG. 6, but incoming light 404 has been shifted three degrees away from the vertical. This change causes the target area to shift to the left, but each of the lenslets still spreads its portion of the beam across the target area. Because the size of the beam in FIG. 7 at the plane of target surface 406 is smaller than the full width of target surface 406, the shifted beam does not spill off target surface 406, because this shift in the beam position is smaller than the width of the blank/unilluminated area, thereby enabling the system to accommodate some amount of pointing error. A shift in the location of the beam (rather than its angle) is illustrated below in connection with FIG. 11.

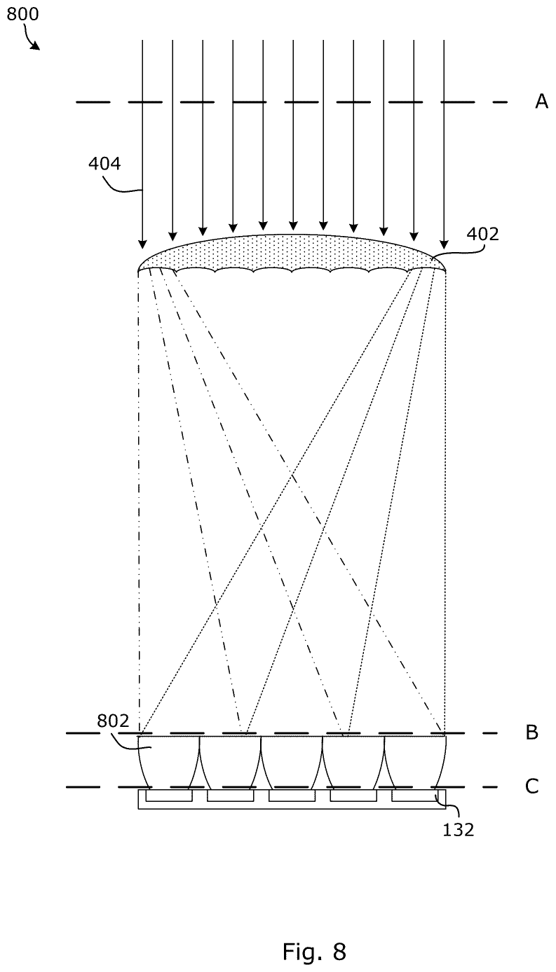

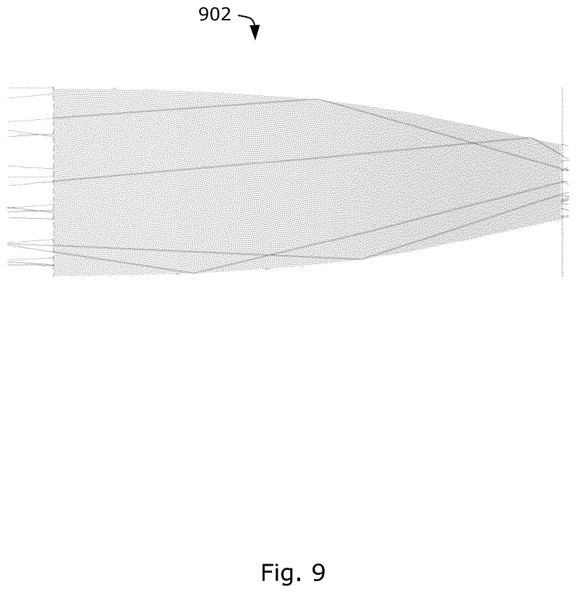

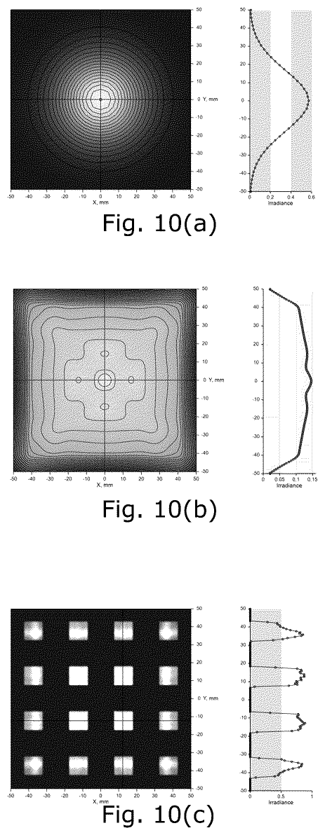

FIG. 8 shows a module 800 including lens 402, a group of concentrators 802 (not all numbered for the sake of clarity), and PV cells 132. The illustrated concentrators are compound parabolic concentrators (CPCs), but other non-imaging concentrators are also contemplated. Incoming light 404 enters lens 402 and is directed toward concentrators 802, which are placed at the location equivalent to target surface 406 as described above, and which concentrate light 404 toward PV cells 132, similarly to the beam splitting apparatus described in co-pending and commonly owned U.S. patent application Ser. No. 17/613,015. A cross-section of one concentrator 802 is shown in FIG. 9. It is a hollow part having polygonal geometry, for example square or hexagonal cross-section, which in some preferred implementations may be densely packed. In some implementations, the output angle for concentrators 802 may be selected to correspond to the maximum acceptance angle of PV cell 132 for improved coupling. The hollow reflective profile shown in FIG. 9 has been chosen to reduce the mass of the receiver as well as assist with internal radiative cooling, but other types of concentrators are also contemplated within the scope of the invention. FIG. 8 also includes three lines A, B, C crossing the path of light 404 as it progresses through lens 402 and to PV cells 132. These represent viewing planes in FIG. 11 FIG. 10-FIG. 13 described below.

### Effectiveness Metrics

FIG. 10 shows how irradiance changes as light moves through module 800. The incoming Gaussian light beam at line A of FIG. 8 is shown at FIG. 10(a). That figure includes a heat map with superimposed contour lines showing the beam irradiance (in arbitrary units), as well as a graph of irradiance along a single line at the highest intensity point. FIG. 10(b) shows how the profile of the light beam has been homogenized at line B, just before it enters the concentrators, and FIG. 10(c) shows the distribution of light at line C, just before it enters the PV cells. (FIG. 10-FIG. 13 each show the same combination of heat maps with contours and 2D graphs along a line of highest intensity in each part, except that the profiles at position C have the contours omitted to improve clarity of the figures.) It can be clearly seen that the light is substantially homogenized by the system and that the optical power on each of the PV cells has been qualitatively equalized relative to what it would have been without the homogenizer. Quantitative analysis of the degree of homogenization is presented below.

FIG. 11 shows how the system responds to a somewhat off-center beam. FIG. 11(a) shows the incoming beam, which is offset from the center of the 100 mm square module by 25 mm in the x- and y-directions. FIG. 11(b) shows how the profile of the light beam has been homogenized at line B, just before it enters the concentrators, and FIG. 11(c) shows the distribution of light at line C, just before it enters the PV cells. While spatial homogenization of an incoming beam may be optimized by the compound lens when the beam is centered along optical axis, the inherent shift-invariant properties of the optics may nevertheless mitigate decentering and ensure uniform filling of second stage optics. It will be seen that, even with only part of the optical element receiving light (see FIG. 11(a)), the light is still quite evenly spread out across most of the target plane as it reaches the PV cells (see FIG. 11(c)).

In some implementations, the full optical element shown in FIG. 8 may include multiples of the module 800 shown in FIG. 8, for example in a 3×3 or 4×4 array. In some implementations, each microlens array may be shaped as illustrated and discussed in FIG. 4-FIG. 6, while in other implementations, the lenslets may be shaped so that each spreads its respective portion of light 404 across a greater portion of the target surface. In such implementations, light from different elements of the multiple modules described above may overlap at the target surface. An advantage of the former arrangement is that modules 800 may all be substantially identical, providing efficiencies in construction. An advantage of the latter arrangement is that incoming light may be more fully equalized across the entire plane. For the sake of simplicity, the following discussion assumes that each module 800 is substantially the same, but those of ordinary skill in the art will understand how modules in the interior of the array may be arranged to spread light into neighboring modules to further equalize the harvested beam.

The modular array design is catadioptric and includes an array of nine square optical modules arranged in a 3×3 pattern, each module including an assembly 800 as shown in FIG. 8. Per-module uniformity at the PV cells is achieved in two stages: the first stage refractive optics (e.g., lens 402) provide some weak concentration (in addition to homogenization) of optical radiation at the entrance to the second stage, and the secondary non-imaging optics 802 (e.g., hollow concentrators, Kohler concentrators, or simple lenses) concentrate the light onto individual PV cells. A function of the staged optics is to shape the quasi-collimated laser input into a spatially homogenized beam within angular acceptance limits matching the secondary non-imaging optics, which ensure the final concentration ratio at each individual PV cell.

FIG. 12 shows the response of the system to a centered high-power Gaussian beam that fills a large portion of the 3×3 aperture of the catadioptric array. For the 300×300 mm array, the beam has a full-width half-max of 119 mm. Very little light is spilled from the edge of the PV array, and each of the nine first-stage optics homogenizes its portion of the incoming beam. FIG. 12(a) shows the beam irradiance as it enters the array (line A), FIG. 12(b) shows the beam irradiance as it enters the concentrators (line B), and FIG. 12(c) shows the beam irradiance as it reaches the PV cells (line C).

Even when the incoming beam is not centered on the array, the system creates a uniform irradiance of the PV cells within each individual module that forms the modular array, as shown in FIG. 13. FIG. 13(a) shows the beam irradiance as it enters the array (line A), FIG. 13(b) shows the beam irradiance as it enters the concentrators (line B), and FIG. 13(c) shows the beam irradiance as it reaches the PV cells (line C).

Qualitatively, the most efficient and cost-effective laser power transmission systems will tend to have light relatively evenly spread across an array, with most PV cells receiving about the same amount of light and with little light either missing the array entirely or entering at such a high angle that the PV cells do not convert it to energy efficiently. We can evaluate arrays to see how well they match this qualitative description by modeling the standard deviation of the irradiance as measured across the array. This parameter is transformed into a dimensionless normalized deviation by dividing it by the average irradiance, removing the arbitrary units. For the systems described in the previous section, we can model the normalized deviation for a single module (for example, the homogenization lens and 4×4 array of PV cells modeled in FIG. 10), making various assumptions about the incoming light beam. We can calculate the normalized deviation at the point where light enters the concentrators.

The normalized deviation will vary depending on the beam profile directed at the module. FIG. 10 is based on a centered Gaussian beam having a full-width half-max of 39.25 mm on an array width of 100 mm, while FIG. 11 shows the same size beam offset from the center of the array by 25 mm in each of the x- and y-axes. We report the normalized deviation both for the centered beam and for the offset beam at planes A and B in FIG. 8. The resulting data are shown in the first two lines of Table 1. The normalized deviation of irradiance is reduced by a factor of at least four by the beam homogenizer.

TABLE 1
Normalized deviations (unitless) for different beam parameters

| | Position A | Position B |
|---|---|---|
| Centered beam | 1.37 | 0.337 |
| Offset beam | 1.62 | 0.297 |
| Large beam - center module | 0.225 | 0.314 |
| Large beam - edge module | 0.907 | 0.335 |
| Large beam - corner module | 1.47 | 0.401 |

For the array of modules shown in FIG. 12 (and FIG. 13), the normalized deviation (averaged over the whole array) would typically be higher for a Gaussian beam arriving at the full array, since each module tends to direct most of the incident light to its own array of PV cells, and thus different modules may be at significantly different irradiance levels. These differences are qualitatively apparent in FIG. 12. In some implementations, the difference may mean that it is more efficient or more cost-effective to use different PV cells, electronics, and/or other components for different modules of the array. For these reasons, the normalized deviation for each module is a more tractable metric. For a 3×3 array of 100 mm square modules and a centered Gaussian beam having a size of 119 mm full-width half max, as shown in FIG. 12, we calculate the normalized deviation for three of the nine modules: the single module at the center, one of the four modules at the edge (orthogonally adjacent to the center module), and one of the four modules at the corners (diagonally adjacent to the center module). The other six will have substantially the same values due to the symmetry of the overall system, so they were not separately modeled. These data are reported in the columns labeled “Large beam” in Table 1. It will be seen that for the center module, the homogenizer makes the beam slightly less uniform (because the homogenizer slightly reduces the beam area, but the “dark edges” are included in the calculation of normalized deviation), while for the edge and corner modules (which have a less homogeneous initial distribution of irradiance), the homogenizer reduces the normalized deviation by a factor of about three or four.

We also confirm that concentrators 802 do not negatively impact the irradiance at the PV cells by modeling the amount of power entering each PV cell in the single module (both with a centered beam and an offset beam). For the centered beam, the normalized light flux (total power at one PV cell divided by average power over all the PV cells) at each PV cell ranges from 0.832 in the corners to 1.29 for the center four cells, with a normalized deviation of 0.177. For the offset beam, the normalized light flux ranges from a minimum of 0.679 to a maximum of 1.38, with a normalized deviation of 0.210. This relatively narrow range means that the mismatch between PV cells is smaller than it would be without the homogenizer (where the normalized deviation would be 1.215 when centered and 1.475 when offset), thereby improving utilization of PV cells and the efficiency.

In some implementations, the PV cells of the modules shown in FIG. 12 and FIG. 13 may be wired in the serial-parallel arrangement, as discussed in our copending and commonly owned International Application No. PCT/US22/13570, but in other implementations, the homogenization across each module may make this type of wiring unnecessary.

The same optical functions modeled and described above could also be accomplished with DOEs (e.g., sub-wavelength DOEs), which can be thinner and therefore much lighter. In one implementation of two-lens Kohler-style optics (which do not homogenize the beam across multiple PV cells), a power beam receiver module (10 cm×10 cm) includes optics weighing 228 grams, and the metal support frame weighs an additional 363 grams, for a total of 591 grams. We estimate that replacing the optics and mounts with the two stages described above would reduce the mass down to ˜115 grams per module, a 5× reduction.

In the following, further features, characteristics, and advantages are described by items:

Item 1: A beam homogenizer includes a compound lens configured to reshape an incident power beam. The compound lens includes a first optical surface configured to focus the incident power beam at a focal distance, and a second optical surface including a plurality of optical elements. Each optical element of the plurality is configured to expand a respective portion of the focused power beam toward a light-gathering area, and the directed portions of the focused power beam each overlap with one another at the light-gathering area to form a homogenized power beam.

Item 2: The beam homogenizer of item 1, wherein the compound lens has a width, and wherein the compound lens is positioned at a distance from the light-gathering area between about half of the width and about six times the width.

Item 3: The beam homogenizer of item 2, wherein the compound lens is positioned at a distance from the light-gathering area between about the width and about four times the width.

Item 4: The beam homogenizer of item 3, wherein the compound lens is positioned at a distance from the light-gathering area between about twice the width and about three times the width.

Item 5: The beam homogenizer of item 1, wherein the compound lens has an axis, the homogenized power beam has a final width that is less than a width of the compound lens, and the light-gathering area is wide enough that the homogenized power beam is positioned within the light-gathering area when the incident power beam forms an angle with the axis of less than 2 degrees.

Item 6: The beam homogenizer of item 5, wherein the light-gathering area is wide enough that the homogenized power beam is positioned within the light-gathering area when the incident power beam forms an angle with the axis of less than 5 degrees.

Item 7: The beam homogenizer of item 5, wherein the light-gathering area is wide enough that the homogenized power beam is positioned within the light-gathering area when the incident power beam forms an angle with the axis of less than 10 degrees.

Item 8: The beam homogenizer of item 1, wherein the incident power beam has an unshaped beam irradiance profile and the homogenized power beam has a reshaped beam irradiance profile, and wherein the reshaped beam irradiance profile is flatter than the unshaped beam irradiance profile.

Item 9: The beam homogenizer of item 8, wherein the unshaped beam irradiance profile is approximately Gaussian.

Item 10: The beam homogenizer of item 9, wherein the reshaped beam irradiance profile is approximately flat across at least half of the light-gathering area.

Item 11: The beam homogenizer of item 8, wherein the reshaped beam irradiance profile has a normalized deviation that is less than half of a normalized deviation of the unshaped beam irradiance profile.

Item 12: The beam homogenizer of item 11, wherein the normalized deviation of the reshaped beam irradiance profile is less than 0.3 times the normalized deviation of the unshaped beam irradiance profile.

Item 13: The beam homogenizer of item 11, wherein the normalized deviation of the reshaped beam irradiance profile is less than 0.25 times the normalized deviation of the unshaped beam irradiance profile.

Item 14: The beam homogenizer of item 11, wherein the normalized deviation of the reshaped beam irradiance profile is less than 0.2 times the normalized deviation of the unshaped beam irradiance profile.

Item 15: The beam homogenizer of item 1, wherein the optical elements have a width of about one-twentieth of a width of the beam homogenizer.

Item 16: The beam homogenizer of item 1, wherein the optical elements have a width of about one-tenth of a width of the beam homogenizer.

Item 17: The beam homogenizer of item 1, wherein the optical elements have a width of about one-fifth of a width of the beam homogenizer.

Item 18: The beam homogenizer of item 1, wherein the optical elements have a width of less than 1 mm.

Item 19: The beam homogenizer of item 1, wherein the optical elements have a width of less than 5 mm.

Item 20: The beam homogenizer of item 1, wherein the optical elements have a width of less than 20 mm.

Item 21: The beam homogenizer of item 1, wherein the optical elements are convex.

Item 22: The beam homogenizer of item 1, wherein the optical elements are concave.

Item 23: The beam homogenizer of item 1, wherein the optical elements are lenslets.

Item 24: The beam homogenizer of item 1, wherein the first side has a first f-number and the second side has a second f-number, and the first f-number and the second f-number have absolute values within 10% of one another.

Item 25: A power receiver includes the beam homogenizer of item 1 and a power converter positioned to receive the homogenized power beam.

Item 26: The power receiver of item 25, further including a concentrator positioned to direct at least a portion of the homogenized power beam toward the power converter.

Item 27: The power receiver of item 26, wherein the concentrator is a reflective concentrator.

Item 28: The power receiver of item 26, wherein the concentrator has an output angle less than or equal to a maximum acceptance angle of the power converter.

Item 29: The power receiver of item 25, further comprising a plurality of concentrators, each concentrator arranged to direct at least a portion of the reshaped power beam towards a particular location in the light-gathering area.

Item 30: The power receiver of item 29, wherein the plurality of concentrators are packed together to collect at least 90% of the reshaped power beam.

Item 31: The power receiver of item 25, wherein the power converter includes a photovoltaic (PV) cell.

Item 32: The power receiver of item 25, wherein the power converter includes a plurality of PV cells.

Item 33: The power receiver of item 32, wherein the power receiver includes a plurality of concentrators, each positioned to receive at least a portion of the homogenized power beam, and each concentrator is positioned to direct its respective portion of the homogenized power beam toward at least one PV cell.

Item 34: A method of homogenizing a power beam includes receiving an incident power beam, splitting the received beam into a plurality of beam portions, and directing each beam portion toward a beam target area. Directing each beam portion includes changing the size of the beam portion at the target area to a selected size, and the plurality of beam portions overlap with one another at the target area.

Item 35: The method of item 34, wherein splitting the beam into a plurality of beam portions and directing each beam portion toward a beam target area include passing the power beam through a compound lens.

Item 36: The method of item 35, wherein the compound lens has an entry surface and an exit surface, and wherein the exit surface includes a plurality of lenslets.

Item 37: The method of item 36, wherein the lenslets are convex.

Item 38: The method of item 36, wherein the lenslets are concave.

Item 39: The method of item 36, wherein the entry surface is aspheric.

Item 40: The method of item 36, wherein the entry surface has a first f-number and the exit side has a second f-number, and the first f-number and the second f-number have absolute values within 10% of one another.

Item 41: The method of item 34, wherein the incident power beam has an incident normalized deviation of beam irradiance, the overlapping plurality of beam portions at the target area have a homogenized normalized deviation of beam irradiance, and the ratio of the homogenized normalized deviation to the incident normalized deviation is less than ½.

Item 42: The method of item 41, wherein the ratio of the homogenized normalized deviation to the incident normalized deviation is less than ⅓.

Item 43: The method of item 41, wherein the ratio of the homogenized normalized deviation to the incident normalized deviation is less than ¼.

Item 44: The method of item 41, wherein the ratio of the homogenized normalized deviation to the incident normalized deviation is less than ⅕.

Item 45: The method of item 34, wherein the plurality of beam portions includes 9-10,000 beam portions.

Item 46: The method of item 34, wherein the plurality of beam portions includes 25-400 beam portions.

Item 47: The method of item 34, wherein the plurality of beam portions includes 64-225 beam portions.

Item 48: The method of item 34, wherein the overlapping beam portions form a homogenized beam.

Item 49: The method of item 48, further including concentrating at least a portion of the homogenized beam.

Item 50: The method of item 49, further including directing the concentrated portion of the homogenized beam to a power converter.

Item 51: The method of item 50, wherein concentrating at least a portion of the power beam includes passing the beam through a concentrator having an output angle less than or equal to a maximum acceptance angle of the power converter.

Item 52: The method of item 34, further including directing the homogenized power beam to a power converter.

Item 53: The method of item 52, wherein the power converter includes a photovoltaic (PV) cell.

Item 54: The method of item 52, wherein the power converter includes a plurality of PV cells.

While the foregoing has described what are considered to the best mode and/or other examples, it is understood that various modifications may be made therein, and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended to be as broad as is consistent with the ordinary meanings of the language that is used in the claims when interpreted in light of this specification and the prosecution history that follows and to encompass all structural and functional equivalents. Notwithstanding, none of the claims are intended to embrace subject matter that fails to satisfy the requirements of Sections 101, 102, or 103 of the Patent Act, nor should they be interpreted in such a way. Any unintended embracement of such subject matter is hereby disclaimed.

Except as stated in the previous paragraph, nothing that has been stated or illustrated is intended or should be interpreted to cause a dedication of any component, step, feature, objects, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity from another without necessarily implying any relationship or order between such entities. The terms “comprise” and “include” in all their grammatical forms are intended to cover a non-exclusive inclusion, so that a process, method, article, apparatus, or composition of matter that comprises or includes a list of elements may also include other elements not expressly listed. An element preceded by “a” or “an” does not, without further constraints, preclude the existence of additional identical or similar elements.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features may be grouped together in various examples for the purpose of clarity of explanation. This method of disclosure is not to be interpreted as reflecting an intention that the claims require more features than are expressly recited in each claim. Furthermore, features from one example may be freely included in another, or substituted for one another, without departing from the overall scope and spirit of the instant application.

1. A beam homogenizer, comprising:
a compound lens configured to reshape an incident power beam, the compound lens including:
a first optical surface configured to focus the incident power beam at a focal distance; and
a second optical surface including a plurality of optical elements tiled to substantially cover the second optical surface, wherein:
each optical element of the plurality is configured to expand a respective portion of the focused power beam toward a light-gathering area; and
the expanded portions of the focused power beam each overlap with one another at the light-gathering area to form a homogenized power beam.

2. The beam homogenizer of claim 1, wherein the compound lens has a width, and wherein the compound lens is positioned at a distance from the light-gathering area between about half of the width and about six times the width.

3.-4. (canceled)

5. The beam homogenizer of claim 1, wherein
the compound lens has an axis;
the homogenized power beam has a final width that is less than a width of the compound lens; and
the light-gathering area is wide enough that the homogenized power beam is positioned within the light-gathering area when the incident power beam forms an angle with the axis of less than 2 degrees.

6.-7. (canceled)

8. The beam homogenizer of claim 1, wherein the incident power beam has an unshaped beam irradiance profile and the homogenized power beam has a reshaped beam irradiance profile, and wherein the reshaped beam irradiance profile is flatter than the unshaped beam irradiance profile.

9. The beam homogenizer of claim 8, wherein the unshaped beam irradiance profile is approximately Gaussian.

10. The beam homogenizer of claim 9, wherein the reshaped beam irradiance profile is approximately flat across at least half of the light-gathering area.

11. The beam homogenizer of claim 8, wherein the reshaped beam irradiance profile has a normalized deviation that is less than half of a normalized deviation of the unshaped beam irradiance profile.

12.-20. (canceled)

21. The beam homogenizer of claim 1, wherein the optical elements are convex.

22. The beam homogenizer of claim 1, wherein the optical elements are concave.

23. The beam homogenizer of claim 1, wherein the optical elements are lenslets.

24. The beam homogenizer of claim 1, wherein the first side has a first f-number and the second side has a second f-number, and the first f-number and the second f-number have absolute values within 10% of one another.

25. A power receiver, comprising:
the beam homogenizer of claim 1; and
a power converter positioned to receive the homogenized power beam.

26. The power receiver of claim 25, further comprising a concentrator positioned to direct at least a portion of the homogenized power beam toward the power converter.

27.-28. (canceled)

29. The power receiver of claim 25, further comprising a plurality of concentrators, each concentrator arranged to direct at least a portion of the reshaped power beam towards a particular location in the light-gathering area.

30. (canceled)

31. The power receiver of claim 25, wherein the power converter includes a photovoltaic (PV) cell.

32. The power receiver of claim 25, wherein the power converter includes a plurality of PV cells.

33. The power receiver of claim 32, wherein:
the power receiver includes a plurality of concentrators, each positioned to receive at least a portion of the homogenized power beam, and
each concentrator is positioned to direct its respective portion of the homogenized power beam toward at least one PV cell.

34. A method of homogenizing a power beam, comprising:
receiving an incident power beam;
splitting the received beam into a plurality of beam portions; and
directing each beam portion toward a beam target area, wherein:
directing each beam portion includes changing the size of the beam portion at the target area to a selected size; and
the plurality of beam portions overlap with one another at the target area.

35. The method of claim 34, wherein splitting the beam into a plurality of beam portions and directing each beam portion toward a beam target area include passing the power beam through a compound lens.

36. The method of claim 35, wherein the compound lens has an entry surface and an exit surface, and wherein the exit surface includes a plurality of lenslets.

37. The method of claim 36, wherein the lenslets are convex.

38. The method of claim 36, wherein the lenslets are concave.

39. The method of claim 36, wherein the entry surface is aspheric.

40. The method of claim 36, wherein the entry surface has a first f-number and the exit side has a second f-number, and the first f-number and the second f-number have absolute values within 10% of one another.

41.-47. (canceled)

48. The method of claim 34, wherein the overlapping beam portions form a homogenized beam.

49. The method of claim 48, further comprising concentrating at least a portion of the homogenized beam.

50. The method of claim 49, further comprising directing the concentrated portion of the homogenized beam to a power converter.

51. The method of claim 50, wherein concentrating at least a portion of the power beam includes passing the beam through a concentrator having an output angle less than or equal to a maximum acceptance angle of the power converter.

52. The method of claim 34, further comprising directing the homogenized power beam to a power converter.

53. The method of claim 52, wherein the power converter includes a photovoltaic (PV) cell.

54. The method of claim 52, wherein the power converter includes a plurality of PV cells.
